(19) United States
(12) Patent Application Publication
(10) Pub. No.: US 2009/0032795 A1
(43) Pub. Date: Feb. 5, 2009

(54) Schottky diode and memory device including the same

(75) Inventors: Dong-chul Kim, Suwon-si (KR); Ran-ju Jung, Suwon-si (KR); Sun-ae Seo, Hwaseong-si (KR); Bae-ho Park, Seoul (KR); Chang-won Lee, Seoul (KR); Hyun-jong Chung, Hwaseong-si (KR); Jin-soo Kim, Namyangju-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/071,099

(22) Filed: Feb. 15, 2008

(30) Foreign Application Priority Data
Aug. 3, 2007 (KR) 10-2007-0078209

(51) Int. Cl. H01L 45/00; H01L 29/24

(52) U.S. Cl. 257/4; 257/43; 257/E29.104; 257/E45.002

(57) ABSTRACT

A Schottky diode and a memory device including the same are provided. The Schottky diode includes a first metal layer and an Nb-oxide layer formed on the first metal layer.

### CROSS-REFERENCE TO RELATED PATENT APPLICATION

This application claims the benefit of Korean Patent Application No. 10-2007-0078209, filed on Aug. 3, 2007, in the Korean Intellectual Property Office, the disclosure of which is incorporated herein in its entirety by reference.

### BACKGROUND OF THE INVENTION

1. Field of the Invention

The present invention relates to a semiconductor device, and more particularly, to a Schottky diode and a memory device including the same.

2. Description of the Related Art

A unit cell of a memory device may be composed of a storage node and a switching device connected to the storage node. The switching device serves to control a signal accessing the storage node connected to the switching device.

In general, a PN diode or a Metal-Oxide-Semiconductor Field Effect Transistor (MOSFET) are used as a switching device. PN diodes and MOSFETs commonly require a junction of well defined P-type and N-type semiconductor layers. However, it is not easy to manufacture a structure in which the well defined P-type and N-type semiconductor layers are combined. This is because a P-type impurity may penetrate/diffuse into the N-type semiconductor layer or an N-type impurity may penetrate/diffuse into the P-type semiconductor layer, and a plurality of defects may occur at the interface (i.e., the P-N junction) of the P-type semiconductor layer and the N-type semiconductor layer. The penetration/diffusion of the impurities, and defects degrade switching characteristics thereof.

In addition, an ion implantation process is required so as to form the P-N junction, and such an ion implantation process is a high cost process that increases manufacturing costs.

### SUMMARY OF THE INVENTION

In order to solve the aforementioned problems, the present invention provides a switching device that is easy to manufacture and is capable of reducing manufacturing costs.

The present invention also provides a memory device including the switching device.

According to an aspect of the present invention, there is provided a Schottky diode including a first metal layer; and an Nb-oxide layer formed on the first metal layer.

A second metal layer may be further formed on the Nb-oxide layer.

An ohmic contact layer may be further formed between the Nb-oxide layer and the first metal layer, or between the Nb-oxide layer and the second metal layer.

According to another aspect of the present invention, there is provided a memory device including a storage node; and a switching device connected to the storage node, wherein the switching device is a Schottky diode comprising a first metal layer and an Nb-oxide layer formed on the first metal layer.

A second metal layer may be further formed on the Nb-oxide layer.

An ohmic contact layer may be further formed between the Nb-oxide layer and the first metal layer, or between the Nb-oxide layer and the second metal layer.

The second metal layer may be a lower electrode of the storage node.

The storage node may include a data storage layer comprising one of a resistance change layer, a phase-change layer, a ferroelectric layer, and a magnetic layer.

The storage node may include a lower electrode, a data storage layer, and an upper electrode which are sequentially stacked.

The data storage layer may be a resistance change layer, and the memory device may be a multi-layer cross point resistive memory device including a 1D(diode)-1R(resistance) cell structure.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional diagram illustrating a Schottky diode, according to an embodiment of the present invention;

FIG. 2 is a graph diagram illustrating a voltage-current characteristic of a Schottky diode, according to another embodiment of the present invention;

FIGS. 3 and 4 are cross-sectional diagrams illustrating a memory device that includes a Schottky diode, according to another embodiment of the present invention; and

FIG. 5 is a perspective view illustrating a multi-layer cross point memory device that includes a Schottky diode, according to another embodiment of the present invention.

### DETAILED DESCRIPTION OF THE INVENTION

A Schottky diode and a memory device including the same according to the present invention will now be described more fully with reference to the accompanying drawings. In the drawings, the thicknesses of layers and regions are exaggerated for clarity. Like reference numerals in the drawings denote like elements.

FIG. 1 is a diagram illustrating a Schottky diode, according to an embodiment of the present invention.

Referring to FIG. 1, an Nb-oxide layer 20 is formed on a first metal layer 10. The first metal layer 10 and Nb-oxide layer 20 comprise the Schottky diode. In other words, a potential barrier that is a Schottky barrier exists at a junction of the first metal layer 10 and Nb-oxide layer 20, and rectification characteristics exist due to the Schottky barrier.

A second metal layer 30 may be further formed on the Nb-oxide layer 20. The second metal layer 30 and the first metal layer 10 may be used as electrodes for applying a voltage to the Schottky diode. An ohmic contact layer (not shown) may be formed between the Nb-oxide layer 20 and the second metal layer 30. Forming of the ohmic contact layer is optional.

In a structure illustrated in FIG. 1, the Schottky diode may be composed of the Nb-oxide layer 20 and the second metal layer 30, instead of the first metal layer 10 and the Nb-oxide layer 20. In such a case, the ohmic contact layer may be formed between the first metal layer 10 and the Nb-oxide layer 20, not between the Nb-oxide layer 20 and the second metal layer 30.

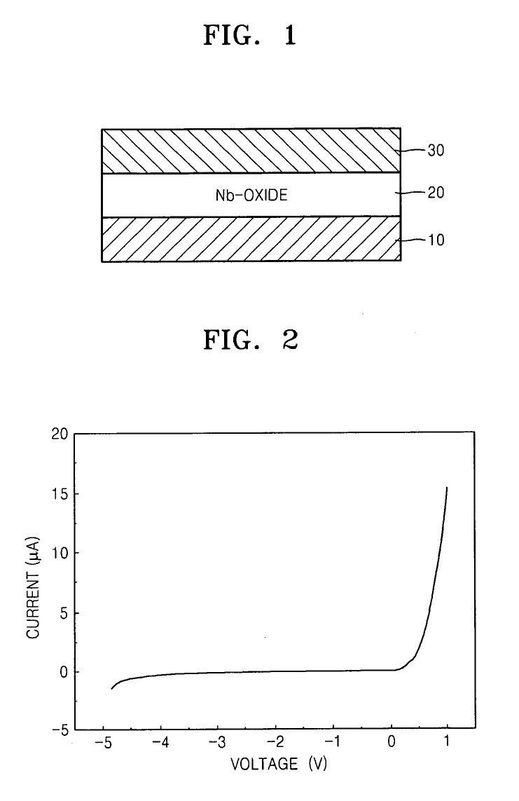

FIG. 2 is a diagram illustrating voltage-current (V-I) characteristics of a Schottky diode, according to the embodiment of FIG. 1 of the present invention. The result illustrated in FIG. 2 is related to a sample that has a structure of FIG. 1, and uses Pt layers as the first and second metal layers 10 and 30. That is, the sample has a Pt/NbₓO_{y}/Pt structure.

Referring to FIG. 2, it can be seen that current increases rapidly with voltage from a predetermined positive voltage onwards, and current does not flow at or beyond a predetermined negative voltage. Thus, this figure clearly shows that the Schottky diode according to the embodiment of the present invention has rectification characteristics.

In the sample having the Pt/NbₓO_{y}/Pt structure, Schottky barriers may respectively exist in interfaces between an NbₓO_{y} layer and an upper Pt layer, and between the NbₓO_{y} layer and a lower Pt layer. However, only one Schottky barrier from among the Schottky barriers, for example, only the Schottky barrier between the lower Pt layer and the NbₓO_{y} layer serves as an effective Schottky barrier. This is because a status of the interface between the lower Pt layer and the NₓO_{y} layer, and a status of the interface between the NbₓO_{y} layer and the upper Pt layer are different. That is, characteristics of the interface obtained by forming the NbₓO_{y} layer on the Pt layer are different from characteristics of the interface obtained by forming the Pt layer on the NbₓO_{y} layer. According to conditions employed when performing vapor deposition of the NbₓO_{y} layer and/or the Pt layer, the obtained characteristics of the interfaces may be different. Thus, without having an ohmic contact layer between the lower Pt layer and the NbₓO_{y} layer, or between the NbₓO_{y} layer and the upper Pt layer, the Pt/NbₓO_{y}/Pt structure may still exhibit rectification characteristics.

The Schottky diode according to an embodiment of the present invention may be easily manufactured by forming an Nb-oxide layer on a metal layer using a Physical Vapor Deposition (PVD) process, a Chemical Vapor Deposition (CVD) process, or an Atomic Layer Deposition (ALD) process. That is, the Schottky diode according to an embodiment of the present invention does not require a junction of well defined P-type and N-type semiconductor layers which is required by PN diodes or Metal-Oxide-Semiconductor Field Effect Transistors (MOSFETs), and does not require an ion implantation process. Thus, the Schottky diode according to an embodiment of the present invention is easy to manufacture and has low manufacturing costs, compared to PN diodes or MOSFETs.

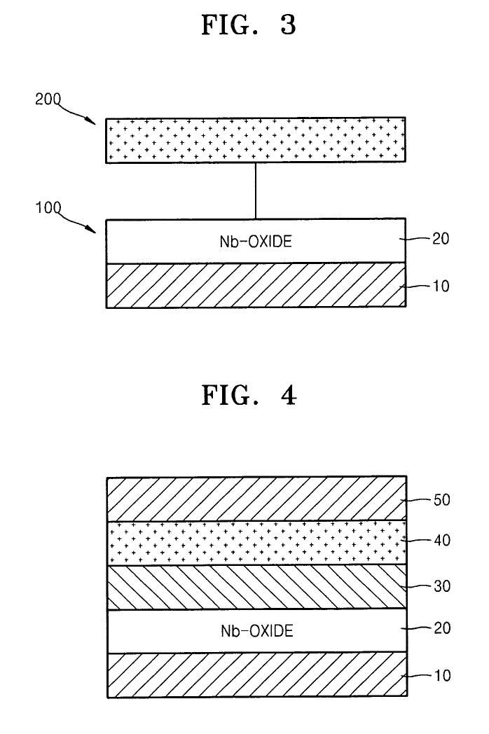

FIG. 3 is a diagram schematically illustrating a unit cell structure of a memory device that uses a Schottky diode 100 as a switching device, according to another embodiment of the present invention.

Referring to FIG. 3, the memory device includes the Schottky diode 100 and a data storage unit 200 connected to the Schottky diode 100. The Schottky diode 100 includes a first metal layer 10, and an Nb-oxide layer 20 on the first metal layer 10. The data storage unit 200 may be a resistance change layer such as an NiₓO_{y} layer. However, the data storage unit 200 may be a phase-change layer, a ferroelectric layer, or a magnetic layer. Various structures of the data storage unit 200 may be employed. The Schottky diode 100 and the data storage unit 200 may be connected via an electrode, and another electrode may be applied to a top surface of the data storage unit 200. In this case, the electrode, the data storage unit 200, and another electrode constitute a storage node. That is, an embodiment of the unit cell structure of FIG. 3 may be as the structure illustrated in FIG. 4.

Referring to FIG. 4, the Nb-oxide layer 20, a second metal layer 30, a data storage layer 40, and an electrode 50 are sequentially formed on the first metal layer 10. The first metal layer 10 and the Nb-oxide layer 20 may constitute a Schottky diode, or alternatively, the Nb-oxide layer 20 and the second metal layer 30 may constitute the Schottky diode. Thus, an ohmic contact layer (not shown) may be further formed between the Nb-oxide layer 20 and the second metal layer 30, or alternatively, the ohmic contact layer may be formed between the first metal layer 10 and the Nb-oxide layer 20. The data storage layer 40 corresponds to the data storage unit 200 of FIG. 3. The second metal layer 30, the data storage layer 40, and the electrode 50 constitute a storage node.

One of the second metal layer 30 and the electrode 50 may have a wire form, and the other of the second metal layer 30 and the electrode 50 may have a dot form. However, various forms of these elements may be employed. For example, all of the second metal layer 30 and electrode 50 may have the wire form and be formed to cross each other, or may be formed to have the dot form. The data storage layer 40 may have various forms. For example, the data storage layer 40 may be formed having a wire form, a dot form, or a plate form.

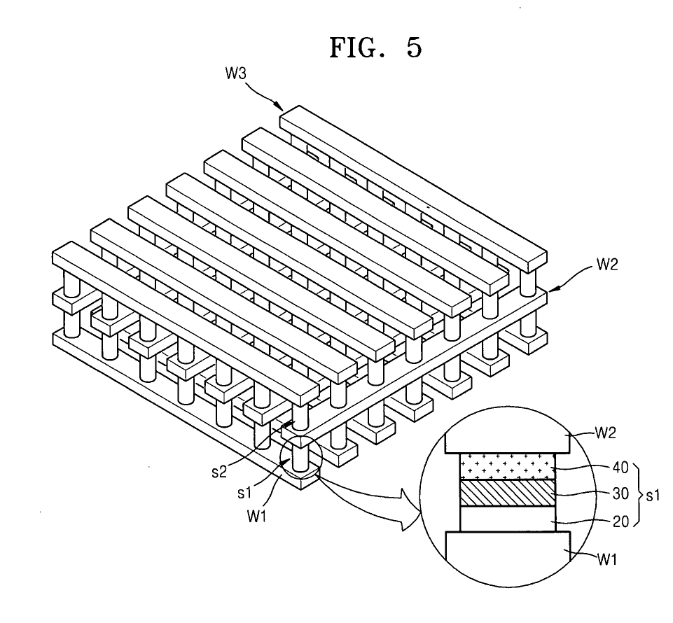

FIG. 5 is a diagram illustrating a multi-layer cross point memory device including a unit cell structure of FIG. 4.

Referring to FIG. 5, a plurality of first wirings W1 are formed on a substrate (not shown) at regular intervals. The first wirings W1 each have a wire form. A plurality of second wirings W2 are formed at regular intervals while being separated a predetermined distance from top surfaces of the first wirings W1. The second wirings W2 may cross the first wirings W1 at right angles.

A first structure s1 is formed at each cross point of the first wirings W1 and the second wirings W2.

Referring to a magnified diagram in FIG. 5, the first structure s1 may include an Nb-oxide layer 20, a second metal layer 30, and a data storage layer 40 which are orderly stacked on the first wiring W1. The Nb-oxide layer 20, the second metal layer 30, and the data storage layer 40 may have a dot form with a similar size.

The first and second wirings W1 and W2 of FIG. 5 respectively correspond to the first metal layer 10 and the electrode 50 of FIG. 4.

A plurality of third wirings W3 may be formed while being separated a predetermined distance from top surfaces of the second wirings W2. The third wirings W3 may be formed at regular intervals, and cross the second wirings W2. A second structure s2 is formed at each cross point of the second wirings W2 and the third wirings W3. The second structure s2 may be identical to the first structure s1. Further structures identical to the first structures s1, and further wirings may be further alternately stacked on the third wirings W3.

In the case where the data storage layer 40 of FIG. 5 is a resistance change layer such as an NiₓO_{y} layer, a structure of FIG. 5 may be a multi-layer cross point resistive random access memory device. At this time, the first wirings W1, the second metal layer 30, and the second wirings W2 may each be a Pt layer, or other metal layers.

Since the switching device (the Schottky diode) according to an embodiment of the present invention uses a contact of a metal layer and an Nb-oxide layer, the switching device may be more easily manufactured at lower cost, compared to PN diodes or MOSFETs which require the well defined PN junction.

In addition, although a size of the Schottky diode is small, since the Schottky diode has a forward current which is larger than that of a PN diode, the Schottky diode may generate enough forward current to operate a device. Thus, when the Schottky diode according to an embodiment of the present invention is used as the switching device of the memory device, integration of the memory device can be increased.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A Schottky diode comprising:
a first metal layer; and
an Nb-oxide layer formed on the first metal layer.

2. The Schottky diode of claim 1, wherein a second metal layer is further formed on the Nb-oxide layer.

3. The Schottky diode of claim 2, wherein an ohmic contact layer is further formed between the Nb-oxide layer and the first metal layer, or between the Nb-oxide layer and the second metal layer.

4. A memory device comprising:
a storage-node; and
a switching device connected to the storage node,
wherein the switching device is a Schottky diode comprising a first metal layer and an Nb-oxide layer formed on the first metal layer.

5. The memory device of claim 4, wherein a second metal layer is further formed on the Nb-oxide layer.

6. The memory device of claim 5, wherein an ohmic contact layer is further formed between the Nb-oxide layer and the first metal layer, or between the Nb-oxide layer and the second metal layer.

7. The memory device of claim 5, wherein the second metal layer is a lower electrode of the storage node.

8. The memory device of claim 4, wherein the storage node comprises a data storage layer comprising one of a resistance change layer, a phase-change layer, a ferroelectric layer, and a magnetic layer.

9. The memory device of claim 4, wherein the storage node comprises a lower electrode, a data storage layer, and an upper electrode which are sequentially stacked.

10. The memory device of claim 9, wherein the data storage layer is a resistance change layer, and the memory device is a multi-layer cross point resistive memory device comprising a 1D(diode)-1R(resistance) cell structure.
